(19) United States
(12) Patent Application Publication
(10) Pub. No.: US 2026/0111640 A1
(43) Pub. Date: Apr. 23, 2026

(54) DATA PROCESSING METHOD AND SYSTEM BASED ON AN FPGA IMPLEMENTATION USING AN IMPROVED NAG ALGORITHM FOR A DUAL-FEMTOSECOND LASER RANGING SYSTEM

(71) Applicant: GUILIN UNIVERSITY OF TECHNOLOGY, Guilin (CN)

(72) Inventors: Guoqing ZHOU, Guilin (CN); Jiajun ZHU, Guilin (CN); Xiang ZHOU, Guilin (CN)

(73) Assignee: GUILIN UNIVERSITY OF TECHNOLOGY, Guilin (CN)

(21) Appl. No.: 19/337,885

(22) Filed: Sep. 23, 2025

(30) Foreign Application Priority Data
Oct. 20, 2024 (CN) 202411463060.7

(51) Int. Cl. G06F 30/347

(52) U.S. Cl. CPC G06F 30/347

(57) ABSTRACT

The disclosure is related to a data processing method and system based on an FPGA implementation using an improved NAG algorithm for a dual-femtosecond laser ranging system. It addresses low ranging accuracy and inefficient FPGA resource use. First, the system acquires pulse signal timestamps and values. Second, optimal learning rate and decay rate parameters are pretrained via grid search in software. Third, the improved NAG algorithm fits the pulse envelope on the FPGA using these parameters, computing the pulse peak time. Finally, the peak time is substituted into the optical distance formula to derive the distance. This approach significantly enhances ranging accuracy while reducing FPGA resource consumption, making it suitable for high-precision applications like atmospheric monitoring and lidar.

### CROSS-REFERENCE TO RELATED APPLICATION

This application claims the priority benefit of China application serial no. 202411463060.7, filed on Oct. 20, 2024. The entirety of the above-mentioned patent application is hereby incorporated by reference herein and made a part of this specification.

### BACKGROUND

### Technical Field

The present disclosure relates to the field of signal processing and laser ranging, and is particularly a data processing method and system based on an Field-Programmable Gate Array (FPGA) implementation using an improved Nesterov Accelerated Gradient (NAG) algorithm for a dual-femtosecond laser ranging system.

### Description of Related Art

Dual femtosecond laser ranging technology, with its advantages of high precision and fast response, has become one of the advanced methods for absolute distance measurement and is widely applied in fields such as atmospheric monitoring, laser radar, and satellite tracking. Relying on the high temporal resolution of femtosecond lasers, this technology achieves absolute distance measurement with extremely high precision. However, to further promote its development and practical application, improving ranging precision and reducing resource consumption are crucial. Therefore, deepening research in this direction is of great significance.

Currently, the data processing method for dual-femtosecond laser ranging systems based on FPGA mainly adopts the Broyden-Fletcher-Goldfarb-Shanno (BFGS) algorithm, as shown below.

The Chinese patent application with Publication No. CN111190190A discloses a hardware structure of a data processing platform for a dual-femtosecond laser ranging system. This disclosure uses the BFGS algorithm for pulse peak detection, and its BFGS-based peak detection module hardware structure includes a computing control module, an objective function evaluation module, a linear search module, a gradient calculation module, and a matrix update module. This platform can realize pulse envelope reconstruction to obtain the center time of the corresponding pulse peak. However, both the ranging precision and resource utilization rate of this disclosure need to be improved.

The paper “Peak Detection Based on FPGA Using Quasi-Newton Optimization Method for Femtosecond Laser Ranging” by Jiang Y et al. details the implementation of the hardware architecture for the Caruana algorithm and the BFGS Quasi-Newton algorithm in data processing of the dual-femtosecond laser ranging system. The paper shows that the Caruana algorithm consumes fewer resources during hardware deployment, but it notably sacrifices accuracy. On the other hand, the hardware architecture based on the BFGS Quasi-Newton algorithm exhibits less accuracy loss, yet it demands a large amount of hardware resources.

The paper “Resource Reduction of BFGS Quasi-Newton Implementation on FPGA using Fixed-Point Matrix Updating” by Jia Liu and others presents a solution for implementing the BFGS Quasi-Newton method on an FPGA. The key of this solution is to reduce resource consumption through fixed-point matrix updating. However, the process of updating the inverse Hessian matrix in this method still takes up a significant amount of computing resources and memory. To address this issue, the paper puts forward a fixed-point hardware design for updating the B matrix and combines it with a retained floating-point operation module to create a mixed-precision Broyden-Fletcher-Goldfarb-Shanno Quasi-Newton (BFGS-QN) implementation, which significantly reduces resource usage.

In the existing technology, the BFGS algorithm offers high accuracy but has high hardware resource consumption. Therefore, the present disclosure proposes a data processing method based on an FPGA implementation using an improved NAG algorithm for a dual-femtosecond laser ranging system. This method is intended to substantially reduce the resource consumption of the BFGS algorithm while considerably enhancing measurement accuracy. Through this improvement, hardware resource usage can be significantly decreased while ensuring accuracy, thus improving the overall performance and efficiency of the system.

### SUMMARY

To address the above problems, the disclosure provides a data processing method based on an FPGA implementation using an improved NAG algorithm for a dual-femtosecond laser ranging system. Compared with the BFGS algorithm, this method can significantly improve the ranging accuracy while reducing FPGA resource occupation. The peak center time is determined by reconstructing the pulse envelope, and then the distance to be measured is calculated.

The present disclosure aims to solve the problems of insufficient pulse peak detection accuracy and excessive hardware resource consumption in the dual-femtosecond laser ranging system, and realize high-precision ranging and efficient hardware collaborative optimization. The specific objectives include:

Improving the detection accuracy of the pulse peak time, reduce the mean value and standard deviation of the fitting deviation through the improved optimization algorithm, and meet the sub-micron level ranging requirements.

Significantly reducing FPGA hardware resource consumption, adopt a modular pipeline design to avoid complex matrix operations, and reducing resource occupation to less than one-fifth of the original scheme.

Breaking through the contradictory barrier between accuracy and resource efficiency, combining software pre-training and hardware dynamic scheduling to simultaneously achieve the dual optimization of accuracy improvement and resource saving.

Enhancing the real-time processing capability of the system, supporting the rapid analysis of high-frequency pulse signals through a pipelined parallel architecture, which is suitable for compact devices such as embedded lidar.

Provide an expandable hardware framework, adapt to multiple fitting functions and ranging scenarios, and reuse the core architecture through parameter configuration to avoid repeated development.

To this end, according to one aspect of the present disclosure, a data processing method for a dual-femtosecond laser ranging system based on an improved NAG algorithm using an FPGA is provided, including the following steps:

Discrete sampling points of the pulse signal are acquired through a dual-femtosecond laser ranging system, wherein the discrete sampling points include time stamps and measured values.

Optimize learning parameters based on the discrete sampling points, wherein the optimization of learning parameters is performed by pre-training an optimal learning rate and a learning rate decay rate in software through grid search.

The optimized learning parameters are used to perform hardware fitting of the pulse envelope on the FPGA, and the hardware fitting of the pulse envelope is implemented by iteratively calculating the pulse peak time through the improved NAG algorithm.

Calculate a distance value based on a pulse peak time output by hardware fitting, wherein calculating the distance value is performed by substituting the pulse peak time into an optical distance calculation formula to solve for the distance value.

Further, the step of hardware fitting the pulse envelope includes scheduling multiple sub-modules through the computing control module to collaboratively execute the improved NAG algorithm, wherein:

The computing control module controls the execution order of the following sub-modules through a finite state machine: a look-ahead position calculation module, an objective function calculation module, a gradient calculation module, an exit judgment module, a learning rate decay module, a momentum update module, and a parameter update module. And the computing control module adopts a dynamic allocation strategy to cache the calculation results of internal variables between the sub-modules in the on-chip Block Random Access Memory (BRAM) of the FPGA.

Further, during the step of hardware fitting of the pulse envelope, the next position is predicted by the look-ahead position calculation module, wherein:

The prediction is based on the current momentum vector and the parameter vector from the previous iteration. The current momentum vector represents the cumulative effect of historical update directions. And the parameter vector from the previous iteration includes the fitting parameters of the Gaussian function.

Further, in the hardware fitting pulse envelope step, the fitting error is generated by the objective function calculation module, wherein:

The objective function calculation module calculates Gaussian function values and the sum of squared errors in parallel; the Gaussian function values take the look-ahead position as input and output the fitting amplitude of the pulse envelope; the sum of squared errors is obtained by comparing the fitting amplitude with the actual observed value point by point.

Further, in the data processing method of the FPGA-based improved NAG algorithm for the dual-femtosecond laser ranging system, in the hardware fitting pulse envelope step, the gradient calculation module solves the gradient by using the forward difference method, where:

The forward difference method generates a perturbed vector by adding a small perturbation value to the parameter vector. The gradient calculation module calculates the objective function difference between the perturbed vector and the original vector in parallel.

The gradient is obtained by dividing the objective function difference by the perturbation value, and it is used to indicate the parameter update direction.

Further, in the hardware fitting pulse envelope step, the iteration termination condition is evaluated by an exit judgment module, wherein:

The evaluation is based on a comparison result between a norm of a gradient vector and a preset threshold. The evaluation also detects whether the current number of iterations reaches an upper limit. The iteration is terminated and a pulse peak time is output when any of the conditions is satisfied.

Further, in the hardware fitting pulse envelope step, the learning rate is dynamically adjusted through the learning rate decay module, wherein:

The dynamic adjustment calculates an attenuation factor based on the number of iterations and a preset attenuation rate. The attenuation factor acts on the initial learning rate through an exponential function. The adjusted learning rate is used to control the parameter update step size.

Further, in the hardware fitting pulse envelope step, the gradient and historical momentum are fused through a momentum update module, wherein:

The fusion is implemented by weighted superposition of a current gradient and a momentum vector at a previous moment; the proportion of the weighted superposition is controlled by a learning rate and a momentum factor; the fusion result generates an updated momentum vector to accelerate parameter convergence.

Further, in the hardware fitting pulse envelope step, the fitting parameters of the Gaussian function are adjusted by a parameter update module in combination with a momentum vector, wherein:

The adjustment is implemented by adding the parameter vector from the previous iteration to the updated momentum vector; the updated momentum vector is output by the momentum update module; the adjustment result generates a new parameter vector to iteratively approach the optimal solution of the pulse envelope.

Further, in the step of calculating the distance value, the pulse peak time is substituted into the optical distance calculation formula through the distance calculation module, wherein:

The calculation formula for the optical distance is based on the timing differences among the peak time of the reference pulse, the peak time of the target pulse, and the peak time of the reference pulse in the next cycle. By combining these timing differences with the speed of light, the refractive index of air, and the laser repetition frequency, the absolute distance can be calculated. The speed of light, the refractive index of air, and the laser repetition frequency are predefined constants.

According to another aspect of the present disclosure, there is also provided a data processing system using an improved NAG algorithm for a dual-femtosecond laser ranging system, comprising:

A data acquisition module is configured to obtain discrete sampling points of a pulse signal, where the discrete sampling points include timestamps and measured values.

A parameter optimization module is connected to the data acquisition module and is configured to output an optimal learning rate and a learning rate decay rate through grid search based on the discrete sampling points.

A pulse envelope fitting module is connected to the parameter optimization module, is deployed on an fpga platform, and includes.

A computing control module configured to schedule an execution process through a finite state machine.

A plurality of hardware sub-modules working collaboratively.

An on-chip bram dynamic cache module connected to each module and configured to store intermediate variables.

A distance calculation module is connected to the pulse envelope fitting module and is configured to output an absolute distance based on the output pulse peak time.

Further, the hardware sub-module of the pulse envelope fitting module includes:

A look-ahead position calculation module that outputs a look-ahead position based on a parameter vector and a momentum vector.

An objective function calculation module connected to the look-ahead position calculation module, which outputs an objective function value based on the look-ahead position and the discrete sampling points.

A gradient calculation module connected to the objective function calculation module, which outputs a gradient vector based on the objective function value.

An exit judgment module connected to the gradient calculation module, which outputs an iteration termination signal based on the gradient vector.

A learning rate decay module that outputs a dynamic learning rate based on the learning rate decay rate output by the parameter optimization module.

A momentum update module connected to the gradient calculation module and the learning rate decay module, which outputs an updated momentum vector based on the gradient vector and the dynamic learning rate.

A parameter update module connected to the momentum update module and the look-ahead position calculation module, which outputs an updated parameter vector based on the updated momentum vector.

The updated parameter vector output by the parameter update module contains the pulse peak time and is input into the distance calculation module.

Further, the on-chip BRAM dynamic cache module executes a sequential overwrite storage strategy, wherein:

In response to a scheduling instruction from the computing control module, the on-chip BRAM dynamic cache module dynamically allocates a storage block to the currently activated hardware sub-module. Immediately after the objective function computing module completes the computation, release its storage block and allocate the released storage block to the gradient computing module. The upper limit of the cache space shared by all hardware sub-modules is 5 BRAM units.

Further, the input of the distance calculation module includes three types of pulse peak times output by the pulse envelope fitting module, wherein:

The first type is a reference pulse peak time; the second type is a target pulse peak time; the third type is a next-cycle reference pulse peak time; the distance calculation module outputs an absolute distance value via scalar multiplication and division, combined with constants of light speed, air refractive index, and laser repetition frequency.

Further, when the distance calculation module calculates the absolute distance value; The peak time of the first type of pulse is used as a time reference point; the peak time of the second type of pulse is used to calculate its time delay relative to the peak time of the first type of pulse; the peak time of the third type of pulse is used to calculate its time delay relative to the peak time of the first type of pulse to determine the complete period of the laser pulse.

The present disclosure significantly improves ranging accuracy through an improved optimization algorithm, with the mean value and standard deviation of the pulse peak time fitting deviation achieving verifiable reductions. It adopts a modular pipeline architecture to greatly compress FPGA resource consumption, reducing the utilization rate of key hardware resources to less than one-fifth of that in traditional solutions. Through the collaborative work of software pre-training and hardware dynamic scheduling, it significantly reduces resource occupation while ensuring improved accuracy. Based on parallel design and pipeline control, it supports real-time processing of high-frequency pulses to meet the rapid response requirements of scenarios such as lidar. By means of a parameterized architecture, it adapts to multiple envelope functions, improves the reuse capability of the hardware platform, and provides an efficient solution for the field of precision ranging.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates the step-by-step process of the method described in the present disclosure.

FIG. 2 shows a block diagram representing the hardware module composition of the improved NAG algorithm of the present disclosure.

FIG. 3 portrays the hardware structure of the look-ahead position calculation module of the present disclosure.

FIG. 4 displays the hardware structure of the objective function calculation module of the present disclosure.

FIG. 5 shows the hardware structure of the gradient calculation module of the present disclosure.

FIG. 6 illustrates the hardware structure of the exit judgment module of the present disclosure.

FIG. 7 depicts the hardware structure of the learning rate decay module of the present disclosure.

FIG. 8 shows the hardware structure of the momentum update module of the present disclosure.

FIG. 9 presents the hardware structure of the parameter update module of the present disclosure.

FIG. 10 makes a comparison between the simulation fitting results of two peak detection algorithms.

### DESCRIPTION OF THE EMBODIMENTS

The present disclosure will be described in further detail below with reference to the accompanying drawings so that those skilled in the art can implement it with reference to the written description.

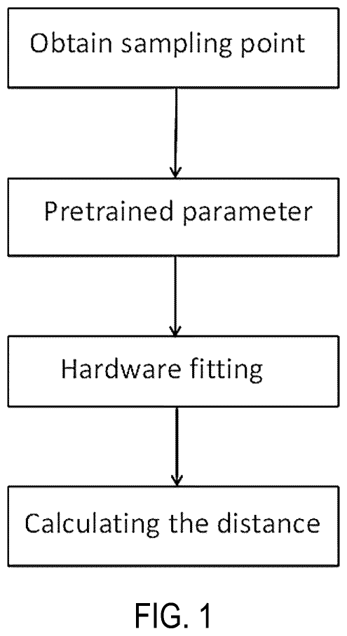

The present disclosure provides a corresponding data processing method for a dual-femtosecond laser ranging system data processing platform. FIG. 1 shows a step flow of the method, and the specific technical solution is as follows:

First: Acquire discrete sampling points (xi, yi) of the pulse signal obtained by a dual femtosecond laser rangefinder, where xi is a timestamp and yi is the corresponding measured value. This dataset will be used for subsequent pulse peak time calculation and distance computation. Meanwhile, parameters measured by a standard interferometer are used as the true distance values to evaluate the algorithm accuracy.

Second: Use Python to adopt a grid search method to select the hyperparameter combination with the minimum loss, apply the improved NAG algorithm for training to obtain the optimal learning rate η₀ and learning rate decay rate λ, and input these parameters as initial values into the FPGA.

Third: Implement the improved NAG algorithm in hardware on the FPGA platform to fit the discrete points and obtain the peak time. The FPGA-based improved NAG algorithm proposed in the present disclosure uses an iterative method to calculate fitting parameters (where k is the number of iterations). According to the calculation process of the NAG algorithm, the hardware architecture of the algorithm can be divided into a computing control module, a look-ahead position calculation module, an objective function calculation module, a gradient calculation module, an exit judgment module, a learning rate decay module, a momentum update module, and a parameter update module.

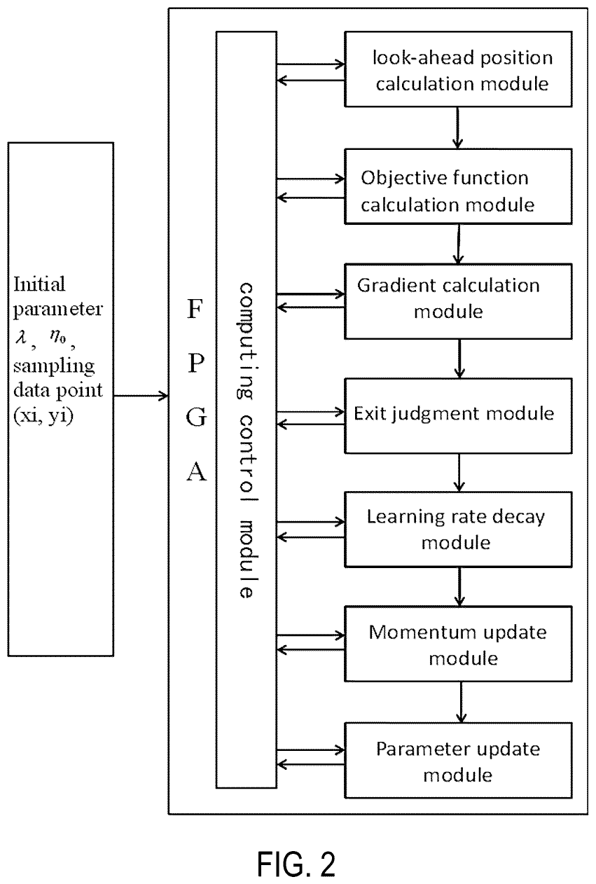

As shown in FIG. 2, the interconnection relationships among various modules and the transmission paths of related internal variables are specifically presented. In the hardware architecture of the improved NAG algorithm, the computing control module precisely schedules the execution sequence of all modules through an optimized finite state machine, invokes the on-chip BRAM to cache the variable computation results between modules by using a dynamic allocation strategy, and realizes efficient transmission of cross-module data. The look-ahead position calculation module predicts the possible next position based on the momentum from the previous step. The objective function calculation module is responsible for solving the objective function of Gaussian fitting during the pulse envelope reconstruction process, which is the sum of squared errors between the observed values and the fitted values. The gradient calculation module uses the forward difference method to calculate the current gradient in real time. The exit judgment module continuously evaluates whether the iteration termination condition is met. The learning rate decay module dynamically calculates the current iteration step size. The momentum update module updates the momentum term by combining the current gradient with the momentum from the previous step, and this momentum term can effectively overcome local irregularities and accelerate convergence. The parameter update module finally executes parameter position update using the updated momentum to complete the core parameter movement step.

Each module of the system adopts a pipeline architecture to process data, that is, the operation process is split into multiple consecutive stages, so that different stages can process independent data blocks in parallel, thereby significantly improving the overall throughput efficiency of the system.

The workflow is as follows:
(1) sampling data points (xi, yi) and initial parameters λ and η₀, and inputting them into a computing control module;
(2) calculating a so-called look-ahead position, which considers the momentum of the previous step to predict the possible position of the next step;
(3) calculating the gradient of the objective function at the predicted position, this step is the core of gradient descent and is used to determine the direction of the steepest descent of the objective function at the current position;
(4) outputting an evaluation result of whether to exit through an exit judgment module;
(5) calculating the learning rate for the current iteration;
(6) updating the momentum based on the current gradient and the momentum of the previous step;
(7) updating the parameter position using the updated momentum, which is the actual parameter movement step;
(8) judging whether the result output by the judgment module meets the exit condition through the computing control module, if the exit condition is met, outputting the fitting result of the peak time; if the exit condition is not met, repeating step (2) of the workflow.

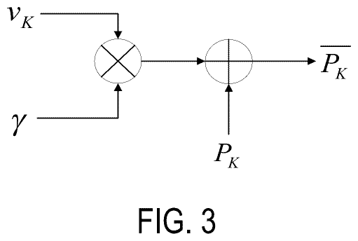

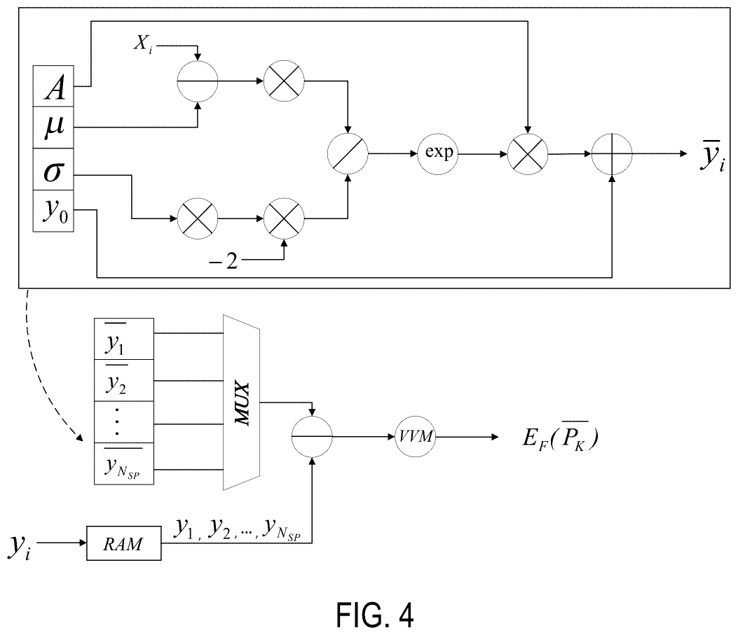

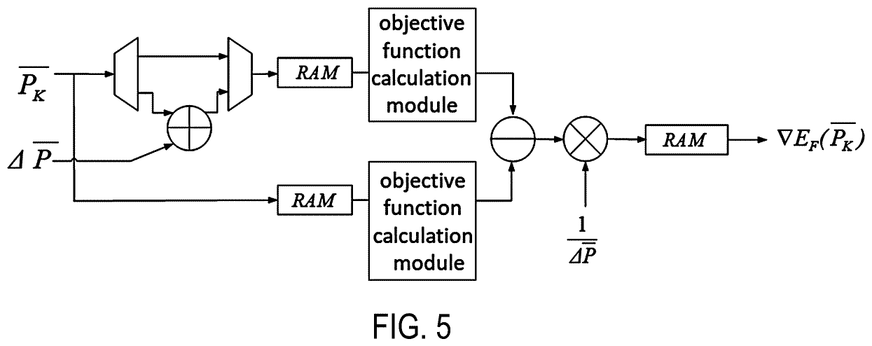

The following will describe in detail the hardware architecture for implementing each functional module on an FPGA platform. The specific hardware implementation scheme is as follows:
1) Look-ahead position calculation module. As shown in attached FIG. 3, it is the hardware architecture of the look-ahead position calculation module, where v_{K} is a momentum vector, γ is a momentum factor set to 0.9, v_{K} and γ are input to a multiplier, and then the result is input to an adder to be added with P_{K} to obtain a momentum-updated look-ahead position vector P̅_̅{̅K̅}̅.
2) Objective Function Calculation Module. As shown in FIG. 4, the hardware architecture of the objective function calculation module is implemented in two parts. The first part obtains a Gaussian function value according to a look-ahead position P̅_̅{̅K̅}̅. The second part calculates an objective function E_{P}(P̅_̅{̅K̅}̅). The upper part of the hardware architecture is the hardware design of a Gaussian function value calculation unit, where (xᵢ−μ) and −2σ² are computed in parallel. The lower part of the hardware architecture is the hardware design of an objective function calculation unit. A multiplexer is used to sequentially select a fitting value and an amplitude of a corresponding sampling data point to flow into a subtracter for subtraction, so as to obtain a difference between the two. Then, the difference is input into a Vector-Vector Multiplication (VVM) unit for a sum of squares operation to obtain an objective function value. The objective function is the sum of squared errors between an observed value and the fitting value.
3) Gradient calculation module. As shown in FIG. 5, it is the hardware architecture of the gradient calculation module. After the objective function calculation module completes the calculation, the gradient calculation module starts to calculate. The gradient calculation module adopts a forward difference design. P̅_̅{̅K̅}̅ is the look-ahead position vector. Each element P̅_̅{̅K̅r̅}̅ of the vector is controlled by a multiplexer to be added with ΔP̅ (0.00001) respectively, so as to obtain 4 groups of new vectors, and the calculation results are stored in the RAM. Another group P̅_̅{̅K̅}̅ is directly stored in the RAM. Two groups of objective function evaluation modules are called for parallel calculation. The two groups of calculation result sequences are sequentially transmitted to both ends of the subtractor. Finally, the result is input to the multiplier and multiplied by

$$\frac{1}{Δ \overline{P}}$$

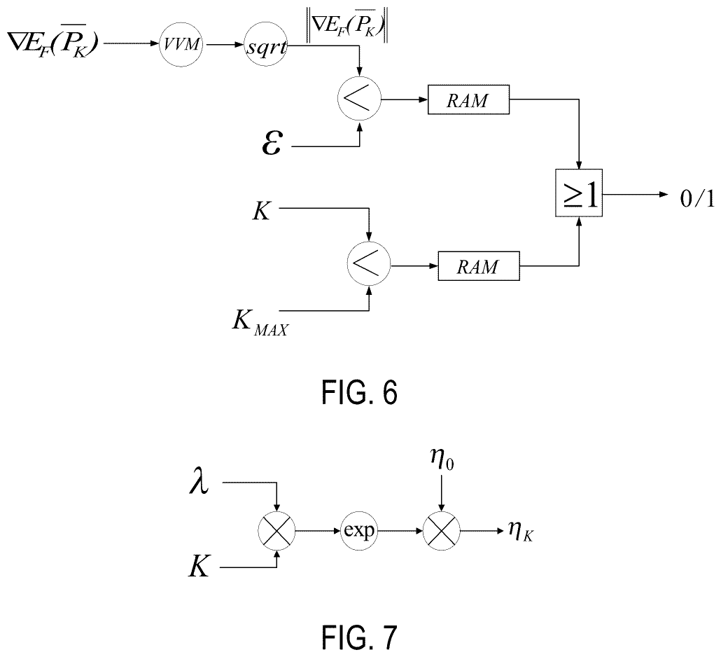

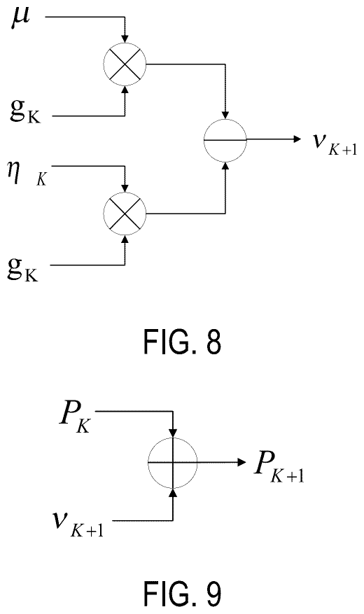

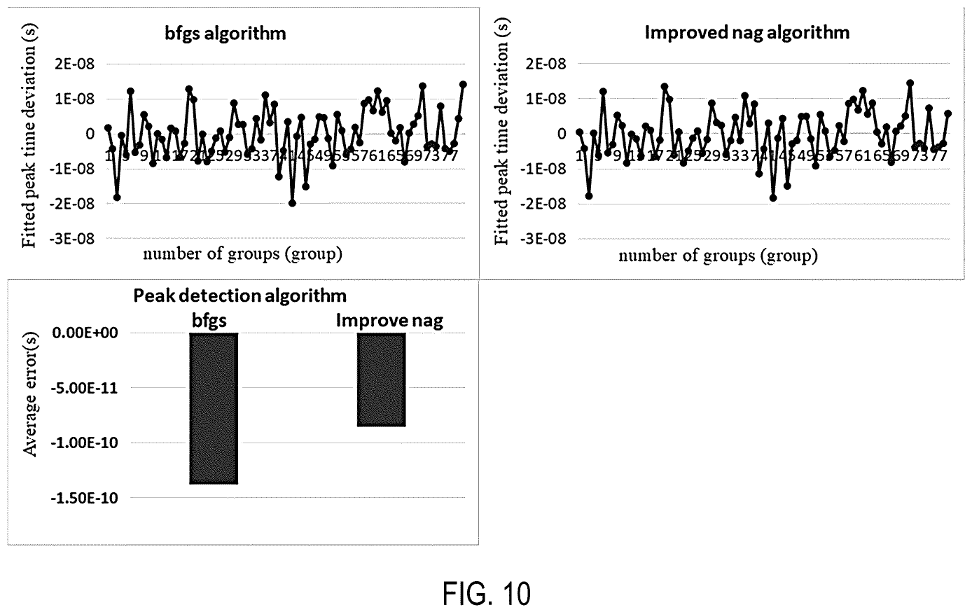

to obtain the gradient ∇E_{F} (P̅_̅{̅K̅}̅) of the objective function at the look-ahead position.
4) Exit judgment module. As shown in FIG. 6, the hardware architecture of the exit judgment module includes a gradient ∇E_{F} (P̅_̅{̅K̅}̅) input Vector Multiplication (VVM) unit, which is used to perform a sum of squares operation, the result of the sum of squares operation is then input into a square root operation (sqrt) unit to obtain a norm ∥∇E_{F}(P̅_̅{̅K̅}̅)∥ of the gradient, the norm of the gradient and a preset threshold ε are then input into a comparator for comparison. If the norm of the gradient is less than the preset threshold ε, the comparator outputs 1; otherwise, it outputs 0. The result of this comparison is stored in a RAM. A current iteration number K and a maximum iteration number K_{MAX} are input into a comparator for comparison. The result of this comparison is stored in the RAM. When the current iteration number is greater than or equal to the maximum iteration number, the comparator outputs 1; otherwise, it outputs 0. The result of this comparison is stored in the RAM. Finally, the two comparison results stored in the RAM are read and input into an or operation. A logical or operation is performed. If either comparison result is true, the logical or operation outputs 1; otherwise, it outputs 0.
5) Learning rate decay module. As shown in FIG. 7, it is the hardware architecture of the learning rate decay module, where λ is the decay rate, K is the number of iterations, and η₀ is the optimal learning rate. λ and K are respectively input into two ends of a multiplier, and then input into an exponential operator (exp), and then input into the multiplier together with η₀ to obtain the learning rate η_{K} at the K-th iteration.
6) Momentum update module. As shown in FIG. 8, which is the hardware architecture of the momentum update module, g_{K} is the gradient, g_{K}=∇E_{F}(P̅_̅{̅K̅}̅). μ and g_{K} are input to both ends of a multiplier, and η_{K} and g_{K} are input to both ends of another multiplier. The results of both multipliers are input to both ends of a subtracter to obtain the updated momentum vector v_{K+1}.
7) Parameter update module. As shown in FIG. 9, which is the hardware architecture of the parameter update module, the updated momentum v_{K+1} and the parameter vector P_{K} are input into both ends of an adder to obtain the updated parameter vector P_{K+1}.

Step 4: Input the obtained reference pulse peak time t_{ref1}, target pulse peak time tₜₐᵣ, and next-cycle reference pulse peak time t_{ref2} into the distance calculation module, and substitute them into the formula to calculate the distance value L to be measured.

Another specific technical solution of the present disclosure is as follows:
Step 1: Data preparation, using a dual femtosecond laser rangefinder to obtain discrete sampling points (xi, yi) of the pulse signal, where xi represents a timestamp and yi represents a corresponding measured value. These data will be used for subsequent pulse peak time calculation and distance calculation. Meanwhile, parameters measured by a standard interferometer are regarded as the true distance values for evaluating the accuracy of the algorithm.
Step 2: Using Python, an improved NAG algorithm is trained by means of grid search to select the combination with the minimum loss, so as to obtain the optimal learning rate η₀ and learning rate decay rate λ, and these are input into the FPGA as initial parameters.
Step 3: On the FPGA platform, based on the collected discrete sampling points, the improved NAG algorithm implemented in hardware is used to perform envelope reconstruction of the pulse signal and iteratively calculate fitting parameters, so as to obtain the center time t corresponding to the pulse peak.
   1) Initialization: Initialize with an Optimal Learning Rate η₀ and a Learning Rate Decay Rate λ.

### 2) Look-Ahead Position Calculation:

$$\overline{{P}_{K}} = {P}_{K} + γ {v}_{K} \qquad ( 1 )$$

$${P}_{K} = [ \begin{matrix}A \\ μ \\ σ \\ {y}_{0}\end{matrix} ] \qquad ( 2 )$$

Equations (1) and (2) relate to forward position calculation and are used to predict possible positions of the next step. Here, v_{K} is a momentum vector, γ is a momentum factor, P̅_̅{̅K̅}̅ is a forward position vector, P_{K} is an input parameter vector, A is a peak value of a Gaussian function, σ is a standard deviation, μ is a mean value representing a center position of the Gaussian function, and y₀ is an offset.

### 3) Calculation of the Objective Function:

$$y ( x ) = A * exp [ - \frac{{( x - μ )}^{2}}{2 {σ}^{2}} ] + {y}_{0} \qquad ( 3 )$$

$${E}_{F} ( \overline{{P}_{K}} ) = {\sum }_{i = 1}^{{N}_{SP}} {\vert \overline{y} ( {x}_{i} , \overline{{P}_{K}} ) - {y}_{i} \vert}^{2} \qquad ( 4 )$$

Equation (3) describes a Gaussian function, and Equation (4) is an expression used to calculate an objective function. The objective function is the sum of squared errors between the model output and the actual observed data. Here, y(x) represents the value of the Gaussian function, and E_{P} (P̅_̅{̅K̅}̅) is the objective function.

### 4) Gradient Calculation:

$$∇ {E}_{F} ( \overline{{P}_{K}} ) = {( ∇ {E}_{F} ( \overline{{P}_{K 1}} ) , ∇ {E}_{F} ( \overline{{P}_{K 2}} ) , ∇ {E}_{F} ( \overline{{P}_{K 3}} ) , ∇ {E}_{F} ( \overline{{P}_{K 4}} ) )}^{T} \qquad ( 5 )$$

$$∇ {E}_{F} ( \overline{{P}_{K r}} ) \approx \frac{{E}_{F} ( \overline{{P}_{K 1}} , \overline{{P}_{K r}} + Δ \overline{P} , \overline{{P}_{K 3}} , \overline{{P}_{K 4}} ) - {E}_{F} ( \overline{{P}_{K 1}} , \overline{{P}_{Kr}} , \overline{{P}_{K 3}} , \overline{{P}_{K 4}} )}{Δ \overline{P}} \qquad ( 6 )$$

Equations (5) and (6) mainly relate to the calculation of the gradient norm and adopt the forward difference method, which is often used in hardware implementation to avoid complex symbolic differentiation. Among them, ∇E_{F} (P̅_̅{̅K̅}̅) is the gradient, that is, the rate of change of the function in different directions; P̅_̅{̅K̅1̅}̅, P̅_̅{̅K̅2̅}̅, P̅_̅{̅K̅3̅}̅, and P̅_̅{̅K̅4̅}̅ are each element of P̅_̅{̅K̅}̅; P̅_̅{̅K̅r̅}̅ is the r-th component of P̅_̅{̅K̅}̅, where r=1, 2, 3, 4; and ΔP̅ is the parameter variation, which is a small perturbation value used in gradient calculation.

### 5) Jump Out Judgment:

$$‖ ∇ {E}_{F} ( \overline{{P}_{K}} ) ‖ = \sqrt{{\sum }_{r = 1}^{4} ∇ {{E}_{F} ( \overline{{P}_{K r}} )}^{2}} \qquad ( 7 )$$

$$( ‖ ∇ {E}_{F} ( \overline{{P}_{K}} ) ‖ < ε ) ⋁ ( K \geq {K}_{MAX} ) \qquad ( 8 )$$

Equation (7) relates to the calculation of a gradient norm, and Equation (8) relates to the judgment of an exit condition. If the gradient norm ∥∇E_{F}(P̅_̅{̅K̅}̅)∥ is less than a threshold &, it indicates that the function value is sufficiently close to the optimal solution and the exit condition is satisfied. If the current number of iterations K is greater than or equal to the maximum number of iterations K_{MAX}, the exit condition is also satisfied. The optimization process stops as long as either of the above two conditions is true. Here, ∥∇E_{F}(P̅_̅{̅K̅}̅)∥ is the norm of the gradient, and K_{MAX} is the maximum number of iterations.

### 6) Learning Rate Decay:

$${η}_{K} = {η}_{0} {e}^{- λ K} \qquad ( 9 )$$

Equation (9) is used to represent a learning rate decay strategy, and it describes how to adjust the learning rate according to the number of iterations during an iterative optimization process. In equation (9), λ is the decay rate, K is the number of iterations, η₀ is the optimal learning rate, and η_{K} is the learning rate at the K-th iteration.

### 7) Momentum Update:

$${g}_{K} = ∇ {E}_{F} ( \overline{{P}_{K}} ) \qquad ( 10 )$$

$${V}_{K + 1} = {μ}_{{V}_{K}} - {η}_{K} {g}_{K} \qquad ( 11 )$$

Equations (10) and (11) describe the momentum update process, where g_{K} is the gradient and v_{K+1} is the updated momentum vector.

### 8) Parameter Update:

$${P}_{K + 1} = {P}_{K} + {V}_{K + 1} \qquad ( 12 )$$

Equation (12) describes a parameter updating process, where P_{K+1} is an updated parameter vector.

A dual-femtosecond laser ranging system based on an FPGA implementation and using an improved NAG algorithm, after reading sampled data from the memory, reconstructs a pulse envelope, and calculates fitting parameters using an iterative method to determine a central time t corresponding to a pulse peak and output a peak time of each pulse. Its hardware implementation includes a computing control module, a look-ahead position calculation module, an objective function calculation module, a gradient calculation module, an exit judgment module, a learning rate decay module, a momentum update module, and a parameter update module, and each module adopts a pipeline structure.

Step 4: Input the obtained reference pulse peak time t_{ref1}, target pulse peak time tₜₐᵣ, and next-cycle reference pulse peak time t_{ref2} into a distance calculation module, and substitute them into the following formula to calculate the distance to be measured L:

$$L = \frac{c}{2 {n}_{g}} \cdot \frac{1}{{f}_{r}} \cdot \frac{{t}_{tar} - {t}_{ref 1}}{{t}_{ref 2} - {t}_{ref 1}} \qquad ( 13 )$$

where c is the speed of light in vacuum, n_{g} is the refractive index of air, and fᵣ is the repetition frequency of the signal laser, all of which are known quantities measured in advance.

### Advantages of the Present Disclosure

### (1) Error Evaluation

Through simulation comparison, the improved NAG algorithm of the present disclosure is significantly superior to the BFGS algorithm in fitting accuracy. Compared with the BFGS algorithm, the improved NAG algorithm reduces the standard deviation of the bias of the fitting result by approximately 1.68% and reduces the mean value of the bias by approximately 38.03%, which significantly improves the fitting accuracy. This indicates that the improved NAG algorithm has higher accuracy and reliability in the dual-femtosecond laser ranging system. The specific accuracy comparison is as follows:

TABLE 1
Comparison of Accuracy between BFGS
Algorithm and Improved NAG Algorithm

| | BFGS algorithm | Improving NAG Algorithm |
|---|---|---|
| Mean value of fitting | −1.377e−10 | −8.532e−11 |
| deviation | | |
| Standard deviation of | 6.908e−09 | 6.793e−09 |
| fitting deviation | | |

### (2) Hardware Resource Utilization Rate

The present disclosure employs a Xilinx FPGA chip and performs functional simulation and logic synthesis using the Verilog hardware description language on the Vivado2020.2 software platform through Xilinx's Electronic Design Automation (EDA) tool Vivado. Through experiments, the resource utilization rate of the improved NAG algorithm of the present disclosure on the FPGA is significantly reduced compared with that of the existing BFGS algorithm, and the specific hardware resource utilization is as follows:

TABLE 2
Comparison of Hardware Resource Utilization among
BFGS Parallel Computing Scheme, BFGS Pipeline
Computing Scheme, and Improved NAG Algorithm

| | | | Digital Signal | |
|---|---|---|---|---|
| | LUT | Flip-Flop (FF) | Processor(DSP) | BRAM |
| BFGS Parallel | 159769 | 193802 | 1210 | 57 |
| Computing | | | | |
| Scheme | | | | |
| BFGS Pipeline | 82661 | 99475 | 606 | 31.5 |
| Calculation | | | | |
| Scheme | | | | |
| Improving the | 14597 | 17619 | 77 | 4.5 |
| NAG Algorithm | | | | |

The detailed description and simulation results of the present disclosure show that the application of the improved NAG algorithm in the dual-femtosecond laser ranging system not only has a significant improvement in calculation accuracy but also shows obvious advantages in terms of FPGA resource utilization, providing a new implementation method for efficient data processing of the dual-femtosecond laser ranging system.

According to another embodiment, through the dual optical path structure of the dual-femtosecond laser ranging system, a high-precision analog-to-digital converter is used to synchronously capture pulse signals at a sampling rate of 20 GS/s, generating a sequence of discrete sampling points containing time stamps (based on an FPGA internal 10 ps precision clock counter) and 16-bit fixed-point amplitude information. A single acquisition covers a 5 ns time window, storing 256 sampling points into an external memory. Based on this set of sampling points, parameter pre-training is performed in an external computing environment. A grid search is conducted using a historical pulse database to traverse combinations within a learning rate range (0.00001 to 0.01) and a decay rate range (0.9 to 0.999). An optimization algorithm simulation is executed for each combination to fit the pulse envelope with a bell curve model and evaluate deviations, screening the optimal parameter combination with the minimum mean square error (exemplary parameters: learning rate 0.0032, decay rate 0.97), which is then transmitted to the FPGA configuration unit through a serial interface.

Execute hardware fitting of the pulse envelope on the FPGA with optimized parameters: Initialize the amplitude, time-center, and pulse-width parameters. Under a 200 MHz clock, iteratively carry out operations. First, generate a look-ahead position by combining the historical momentum with the previous parameters. Second, calculate the theoretical envelope curve in parallel and compare it with the actual sampling points to obtain an error. Third, determine the gradient by calculating the change in the objective function after adding a perturbation of the order of 1×10⁻⁶. Terminate the process when the amplitude of the gradient is below the threshold of 1×10⁻⁸ or the number of iterations exceeds 100. Dynamically reduce the learning rate according to the number of iterations (multiply the initial value by an exponential decay factor). Then, generate a new momentum vector by fusing the current gradient with the historical momentum with a weight of 0.9. Finally, update the pulse envelope parameters. This architecture compresses the on-chip storage resources through the reuse of computing resources.

Based on the output pulse time center value, the distance calculation module processes three types of time markers. The peak time of the reference optical path pulse serves as a reference point. The peak time of the target reflected optical path pulse is used to calculate the relative time delay. The peak time of the reference pulse in the next cycle determines the laser repetition period. By integrating the preset speed of light constant, air refractive index, and laser repetition frequency (100 MHz), high-precision distance measurement is achieved. This solution has been experimentally verified to simultaneously achieve the goals of accuracy improvement and resource compression.

According to another embodiment of the present disclosure, a dual-channel 25 GS/s high-speed ADC analog-to-digital converter is used to synchronously acquire femtosecond laser pulse signals. Each channel captures 512 discrete sampling points within a 6 ns time window. The time stamp is generated by a digital clock manager with 15 ps precision inside the FPGA. The measured values are stored in a DDR4 external memory in an 18-bit fixed-point number format. The error of the synchronous trigger signal is controlled within ±0.8 ps. The system realizes real-time transmission of sampling data through the JESD204B protocol and establishes a double buffering mechanism to avoid data loss.

A parameter pre-training platform is constructed in the Matrix Laboratory (MATLAB) environment, where the learning rate search range is set to 0.0001-0.05 and the decay rate range is set to 0.85-0.995. A Bayesian optimization algorithm is adopted to replace grid search, and parameter combination evaluation is performed based on 500 groups of historical pulse data sets. The mean absolute error (MAE) is used as an indicator to screen the optimal parameters. A typical optimization result is a learning rate of 0.0045 and a decay rate of 0.983, which shortens the training cycle to 12 hours. The parameter configuration is transmitted to the configuration register group of the FPGA through the PCIe interface.

An improved NAG algorithm is deployed on a Xilinx UltraScale+ FPGA and driven by a 250 MHz main clock. A look-ahead position calculation module integrates 4 DSP48E2 hard cores to implement parallel weighted calculation of parameter vectors and momentum vectors. An objective function module has 32 built-in parallel Gaussian function calculation units to complete the sum of squared errors accumulation for 256 sampling points in a single cycle. The gradient calculation uses a perturbation value of 5e−7 and implements differential calculation through a dual-path objective function evaluation module. A dynamic learning rate decay module supports an exponential decay range of 0.95-0.9999, the iteration termination threshold is set to 5e−9, and the maximum number of iterations is extended to 150. The on-chip BRAM adopts a 6-unit shared cache architecture to realize zero-delay switching of data between sub-modules.

The distance calculation module is integrated with a 32-bit floating-point arithmetic unit. The input parameters consist of the reference pulse peak time (with a reference time error of less than 0.6 ps), the target pulse peak time (with a time-delay resolution of 0.3 ps), and the next—cycle reference pulse time (with a cycle stability reaching 1e−9). Relying on the corrected air refractive index of 1.00028 and the 120 MHz laser repetition frequency, a three-stage pipeline structure is used to perform the timing difference calculation. The absolute accuracy of the ultimately output distance value can reach ±1.5 μm, and the data refresh rate allows for 100 kHz real-time output.

The calculation process of the working timing difference of the three-stage pipeline structure of the distance calculation module is as follows:

First stage: Receive three types of peak time data including a reference pulse, a target pulse, and a reference pulse of a next cycle output by a pulse envelope fitting module, and perform a reference time alignment operation in parallel. A peak time of the reference pulse is stored in a register group as a time reference point. A peak time of the target pulse undergoes a timestamp subtraction operation with the time reference point to obtain an initial time delay difference. Meanwhile, a peak time of the reference pulse of the next cycle and the reference point perform a time delay difference calculation for cycle verification.

This stage implements data preprocessing through a dual-channel parallel subtractor to eliminate phase errors introduced by clock jitter.

Second stage: Input the original time delay difference output by the first stage into a calibration unit, and calculate a complete cycle number by combining with a laser repetition frequency. Use the time delay difference of the reference pulse of the next cycle to verify cycle integrity. Dynamically adjust a cycle multiple through a shift register to ensure that the time delay difference calculation is within an integer multiple range of a laser pulse cycle. This stage adopts a dynamic compensation mechanism, judges whether the time delay difference crosses a cycle boundary through a comparator, and performs cycle expansion correction on time delay data exceeding a single cycle range.

Third stage: Input the calibrated time delay difference and a cycle expansion value into a scalar operation unit, and perform a light speed conversion and a refractive index compensation calculation. The time delay difference data flows through a multiplier to perform product operations with constants of light speed and refractive index. Then, complete a distance conversion by dividing by the laser repetition frequency through a divider. This stage integrates error correction logic to perform rounding compensation on quantization errors generated by internal operations of an FPGA, and finally outputs a high-precision absolute distance value. Data seamless connection between the three stages is realized through dual-buffer registers, and a set of complete data processing is completed in each clock cycle.

This structure achieves maximum throughput through time sequence division: when the second stage is processing the Nth group of data, the first stage has already started processing the (N+1)th group of sampling points, and the third stage outputs the (N−1)th group of calculation results simultaneously. At the hardware level, a pipeline register with a depth of 8 is used to eliminate combinational logic delay, the critical path is optimized to 3.2 ns, and real-time processing under a 100 MHz clock is supported.

The scheme realizes collaborative design through three dimensions of parameter optimization, hardware architecture improvement and precision control. While maintaining sub-micron ranging precision, it reduces the Look-Up Table (LUT) resource consumption to 17.3% of the original scheme and decreases the BRAM utilization by 84%.

According to yet another embodiment of the present disclosure, the method includes:

### I. System Initialization Phase

1. Data input preparation: receiving discrete sampling point data from a dual-femtosecond laser ranging system, the discrete sampling point data including a timestamp and a measurement value sequence (such as 256 sampling points), and storing the discrete sampling point data into an FPGA external memory.
2. Parameter loading: writing parameters such as a pre-trained optimal learning rate (such as 0.0032) and a learning rate decay rate (such as 0.97) of software into an FPGA configuration register through a serial port.

### II. Pulse Envelope Fitting Stage (Core Iterative Process)

1. Finite State Machine Activation: The computing control module activates the finite state machine and sets the initial state to “look-ahead position calculation”.
2. Look-ahead Position Prediction: The look-ahead position calculation module reads the current parameter vector (including Gaussian function mean, standard deviation, etc.) and the previous momentum vector, and performs a weighted calculation: new position=parameter vector+0.9*momentum vector. The calculation result is temporarily stored in the dynamically allocated BRAM block #1.
3. Error Evaluation: The objective function calculation module performs two tasks in parallel. It calculates the Gaussian function value (theoretical amplitude) corresponding to the look-ahead position. It also compares the theoretical value with the actual measured value point by point and accumulates the sum of squared errors. After completion, BRAM #1 is released, and the result is transferred to BRAM #2 for storage.
4. Gradient Calculation: The gradient calculation module applies a small perturbation (such as +0.00001) to the parameter vector to generate 4 groups of perturbation vectors. It calculates the objective function values after perturbation in parallel. It then computes (perturbation error-original error)/perturbation value to obtain the gradient vector. BRAM #2 is used to store intermediate data.
5. Iteration Termination Judgment: The exit judgment module performs dual detection. It calculates the modulus of the gradient vector and compares it with a threshold (such as 1e−8). It also counts whether the current number of iterations reaches the upper limit (such as 100 times). If either condition is met, jump to the distance calculation stage.
6. Learning Rate Adjustment: The learning rate decay module calculates the decay factor based on the current number of iterations (K): learning rate=initial value×e\hat{ }(−decay rate×K). The result is written into a dedicated register.
7. Momentum Fusion Update: The momentum update module performs a weighted superposition of the current gradient (with a weight of 0.1) and the historical momentum (with a weight of 0.9) to generate a new momentum vector. The updated value is stored in BRAM #3.
8. Parameter Iterative Optimization: The parameter update module adds the new momentum vector to the original parameter vector to generate updated Gaussian function parameters. The new parameters are fed back to the look-ahead position calculation module to start the next iteration.

### III. Resource Dynamic Management Mechanism

1. Storage Allocation Strategy: Five BRAM units form a shared buffer pool. The state machine allocates one BRAM unit to the activation module, such as #2 occupied by the objective function calculation. Resources are released immediately after the module completes the calculation, such as releasing #2 immediately after the gradient calculation ends.
2. Pipeline Control: When the Nth iteration performs parameter update, the (N+1)th iteration has started data prefetching, and zero waiting is achieved through a double buffering mechanism.

### IV. Distance Calculation Stage

1. Peak Time Extraction: Parse the Gaussian function mean parameter from the final parameter vector, which is the pulse center time.
2. Time Sequence Difference Calculation: Compare the time differences among the peak times of the reference pulse, the target pulse, and the reference pulse of the next cycle.
3. Physical Quantity Conversion: Substitute the time difference into the formula L=(c/n)*Δt/(2f), where c is the speed of light, n is the air refractive index, and f is the laser frequency. The calculation result is output through Gigabit Ethernet.

### V. Key Technical Features

1. Precision Assurance: Local optima are overcome through momentum accumulation (historical gradient memory), and a dynamic learning rate is incorporated to achieve a time resolution of 0.1 picoseconds.
2. Resource Optimization: Compared with traditional solutions, the BRAM usage is reduced from 31.5 units to 4.5 units, representing an 85% reduction.
3. Real-time Performance: At a main frequency of 200 MHz, the time consumed for a single iteration is 5 nanoseconds, and distance calculation is completed within 0.5 microseconds after 100 iterations.

This solution achieves a balance between sub-micron ranging precision and millisecond-level response speed on the Xilinx UltraScale+ FPGA through three core technologies: modular pipeline design, dynamic resource scheduling, and momentum-accelerated convergence.

According to yet another embodiment of the present disclosure, a data processing system using an improved NAG algorithm for a dual-femtosecond laser ranging system. The data processing system includes a data acquisition module, a parameter optimization module, a pulse envelope fitting module, and a distance calculation module. The data acquisition module is responsible for receiving dual femtosecond laser pulse signals from a photodetector, performing digital sampling on the pulse signals using a high-speed analog-to-digital converter, and generating a sequence of discrete sampling points that include precise timestamps and corresponding signal amplitudes. This module ensures that the sampling rate and resolution meet the femtosecond-level time measurement accuracy requirements, and transmits the discrete sampling points to subsequent modules.

The parameter optimization module receives the discrete sampling point sequence provided by the data acquisition module and executes a grid search algorithm to determine the optimal hyperparameter combination for improving the NAG algorithm. This module runs on the central processing unit. First, it sets the search ranges and step sizes for the learning rate and the learning rate decay rate, and then traverses all possible parameter combinations. For each set of parameter combinations, it invokes the improved NAG algorithm to perform preliminary fitting on the current sampling point data and calculates the loss function value between the fitting result and the actual sampling points. By comparing the loss function values corresponding to all parameter combinations, it selects the learning rate and the learning rate decay rate that minimize the loss function as the optimal hyperparameters for output.

The pulse envelope fitting module is deployed on a field-programmable gate array platform. It receives the optimal learning rate and learning rate decay rate output by the parameter optimization module, as well as the discrete sampling points from the data acquisition module. The core of this module is to adopt an improved Nesterov accelerated gradient algorithm to perform high-speed fitting on the discrete sampling points, so as to accurately extract the laser pulse envelope and determine its peak position. The pulse envelope fitting module internally includes a computing control module, multiple hardware sub-modules working collaboratively, and an on-chip BRAM dynamic cache module. The computing control module is implemented using a finite state machine. It is responsible for scheduling the execution flow of the entire improved NAG algorithm, including state transition control such as initialization, iterative calculation, convergence judgment, and result output. The multiple hardware sub-modules working collaboratively are composed of dedicated hardware logic circuits. They include a gradient calculation unit, a look-ahead point calculation unit, a parameter update unit, and a convergence judgment unit. These units execute the core calculation steps of the improved NAG algorithm in parallel under the scheduling of the computing control module. The on-chip BRAM dynamic cache module is integrated inside the FPGA chip. It serves as a high-speed memory connected to all calculation units and is used for real-time storage and reading of intermediate variables during the iterative process. These intermediate variables include current parameter estimates, historical gradient information, look-ahead point parameters, and temporary calculation results, ensuring efficient data flow between hardware sub-modules. The specific execution process of the improved NAG algorithm is as follows. First, initialize the parameters of the pulse envelope model. Then, in each iteration, calculate the look-ahead point parameters based on the current parameters and historical gradient. Calculate the gradient of the loss function at the look-ahead point parameters. Update the model parameters and historical gradient information according to this gradient, the optimal learning rate, and the learning rate decay rate. The iteration continues until the parameter variation is less than a preset threshold or the maximum number of iterations is reached, and then output the finally fitted pulse envelope model parameters and the timestamp corresponding to the peak value.

The distance calculation module receives the precise time information of the laser pulse peak output by the pulse envelope fitting module. This module is based on the dual femtosecond laser ranging principle. It calculates the absolute distance value of the target to be measured by calculating the difference in the arrival time of the pulse peak between the reference optical path and the measurement optical path and combining the propagation speed of light in the air. The module includes a time difference calculation unit and a distance conversion unit, which perform final processing on the peak time data and output the distance measurement result.

The workflow of the entire system is as follows: a data acquisition module continuously acquires discrete sampling points of laser pulses; a parameter optimization module uses these sampling points to determine optimal hyperparameters through grid search; a pulse envelope fitting module, on an FPGA, utilizes the optimal hyperparameters and sampling point data to quickly fit a pulse envelope and locate a peak time through a hardware-implemented improved NAG algorithm; a distance calculation module calculates and outputs an absolute distance value based on a peak time difference, thereby achieving high-precision and real-time dual-femtosecond laser ranging.

According to yet another embodiment of the present disclosure, there is provided a data processing system for a dual-femtosecond laser ranging system with an improved NAG algorithm. The data processing system is used to process discrete sampling point data collected by the dual-femtosecond laser ranging system, determine a pulse peak time through pulse envelope fitting, and output the pulse peak time to a distance calculation module. The system is implemented in hardware and includes multiple sub-modules of a pulse envelope fitting module to ensure efficient iterative optimization. System inputs include a sequence of discrete sampling points from the laser ranging system and a learning rate decay rate provided by a parameter optimization module. The system output is an updated parameter vector containing the pulse peak time, which is directly input into the distance calculation module to calculate the target distance. The entire system achieves fast convergence through the improved NAG algorithm, and the specific implementation process is as follows.

The discrete sampling point data is first input into the hardware submodule of the pulse envelope fitting module. The initial parameter vector of this module includes fitting parameters such as pulse position, width, and amplitude, and the initial momentum vector is a zero vector. The look-ahead position calculation module receives the current parameter vector and momentum vector, and calculates the look-ahead position based on the NAG algorithm. The look-ahead position represents the predicted pulse envelope position and is used to evaluate the optimization direction in advance. For example, the initial value of the parameter vector is set to the middle position of the sampling point sequence and the default width, and the initial value of the momentum vector is a zero vector; the look-ahead position calculation module outputs the adjusted position value through vector operations.

After the look-ahead position is output, the objective function calculation module receives the look-ahead position and discrete sampling point data and calculates an objective function value. The objective function is defined as a pulse envelope fitting error, which is obtained by comparing the mean square error between the fitting curve at the look-ahead position and the actual sampling points. For example, if the discrete sampling points include 1000 data points, the objective function calculation module outputs a scalar value indicating the magnitude of the current fitting error.

The objective function value is input into a gradient calculation module, which calculates a gradient vector of the objective function with respect to parameters. The gradient vector represents a rate of change of fitting error and is used to guide an optimization direction. For example, the gradient calculation module outputs a vector with the same dimension as a parameter vector through a numerical difference method, where the vector includes partial derivatives of parameters such as position and width.

The gradient vector is output to an exit judgment module, which checks whether a norm of the gradient vector is less than a preset threshold. If the norm is less than the threshold, it indicates that optimization converges, and the module outputs an iteration termination signal. Otherwise, iteration continues. For example, the threshold is set to 0.001, the gradient norm is calculated as a square root of a sum of squares of each element of the gradient vector, and a high-level signal is output to indicate termination.

Meanwhile, a learning rate decay module receives a learning rate decay rate provided by a parameter optimization module and outputs a dynamic learning rate. The dynamic learning rate is gradually reduced based on an initial learning rate and the decay rate to control an optimization step size. For example, the initial learning rate is 0.1, the decay rate is 0.95, and the dynamic learning rate is output as the initial value multiplied by the decay rate raised to the power of the number of iterations.

The gradient vector and the dynamic learning rate are input into a momentum update module, which updates a momentum vector based on the gradient vector and the dynamic learning rate. The momentum update employs the NAG algorithm and combines historical gradient information to accelerate convergence. For example, the momentum update module outputs an updated momentum vector, where the new momentum vector is obtained by multiplying the original momentum vector by a momentum factor and then adding the product of the gradient vector and the dynamic learning rate.

The updated momentum vector is input into a parameter update module, which outputs an updated parameter vector based on the momentum vector. The parameter update module adjusts values of the parameter vector, including pulse position, width, etc., and ensures that the pulse peak time is included. For example, the parameter vector is updated to be the original vector minus the momentum vector, and the pulse peak time is directly derived from the position parameter.

The system conducts iterative execution of the aforementioned process. The look-ahead position calculation module utilizes the updated parameter vector and momentum vector to recalculate the look-ahead position. The objective function calculation module updates the value of the objective function according to the new look-ahead position and discrete sampling points. The gradient calculation module recalculates the gradient vector. The exit judgment module checks if the process should be terminated. The iteration persists until the exit judgment module outputs a termination signal.

Ultimately, the updated parameter vector output by the parameter update module includes the precise pulse peak time. This vector is then input into the distance calculation module to calculate the target distance. The system's data flow guarantees that the parameter vector, momentum vector, and gradient vector change dynamically during each iteration, enabling efficient fitting.

The entire system can be deployed on FPGA or ASIC hardware. It processes real-time sampling point data and outputs the stable peak time.

Although the embodiments of the present disclosure have been disclosed as above, they are not limited merely to the applications listed in the specification and the embodiments. They can be fully applied to various fields suitable for the present disclosure. For those skilled in the art, additional modifications can be easily made. Therefore, without departing from the general concept defined by the claims and the scope of equivalents, the present disclosure is not limited to the specific details and the legends shown and described herein.

What is claimed is:

1. A data processing method based on an FPGA implementation using an improved NAG algorithm for a dual-femtosecond laser ranging system, wherein the data processing method comprises the following steps of:
discretizing sampling points of a pulse signal are acquired through the dual-femtosecond laser ranging system, wherein the discretized sampling points include timestamps and measured values;
optimizing learning parameters based on the discretized sampling points, wherein the optimizing of the learning parameters is performed by pre-training a desired learning rate and a learning rate decay rate in a software through grid search,
wherein the optimized learning parameters are used to perform a hardware fitting of a pulse envelope on the FPGA, and the hardware fitting of the pulse envelope is implemented by iteratively calculating a pulse peak time through the improved NAG algorithm; and
calculating a distance value based on the pulse peak time outputted by hardware fitting, wherein calculating the distance value is performed by substituting the pulse peak time into an optical distance calculation formula to solve for the distance value.

2. The data processing method based on the FPGA implementation using the improved NAG algorithm for the dual-femtosecond laser ranging system according to claim 1, wherein:
the step of hardware fitting the pulse envelope includes scheduling a plurality of sub-modules to cooperatively execute the improved NAG algorithm through a computing control module, wherein;
the computing control module controls an execution order of the following sub-modules through a finite state machine: a look-ahead position calculation module, an objective function calculation module, a gradient calculation module, an exit judgment module, a learning rate decay module, a momentum update module, and a parameter update module, and the computing control module adopts a dynamic allocation strategy to cache calculation results of internal variables between the sub-modules in an on-chip BRAM of the FPGA.

3. The data processing method based on the FPGA implementation using the improved NAG algorithm for the dual-femtosecond laser ranging system according to claim 2, wherein:
in the step of hardware fitting the pulse envelope, a next position is predicted by the look-ahead position calculation module, wherein:
the predicting of the next position is based on a current momentum vector and a parameter vector from a previous iteration, the current momentum vector represents a cumulative effect of historical update directions, and the parameter vector from the previous iteration includes fitting parameters of a Gaussian function.

4. The data processing method based on the FPGA implementation using the improved NAG algorithm for the dual-femtosecond laser ranging system according to claim 1, wherein:
in the step of hardware fitting the pulse envelope, a fitting error is generated by an objective function calculation module, wherein:
the objective function calculation module calculates Gaussian function values and a sum of squared errors in parallel; the Gaussian function values take a look-ahead position as input and output a fitting amplitude of the pulse envelope; and the sum of the squared errors is obtained by comparing the fitting amplitude with an actual observed value point by point.

5. The data processing method based on the FPGA implementation using the improved NAG algorithm for the dual-femtosecond laser ranging system according to claim 1, wherein:
in the step of hardware fitting the pulse envelope, a gradient calculation module solves a gradient using a forward difference method, wherein:
the forward difference method generates a perturbed vector by adding a perturbation value to a parameter vector, the gradient calculation module calculates an objective function difference between the perturbed vector and an original vector in parallel, the gradient is obtained by dividing the objective function difference by the perturbation value and used to indicate a parameter update direction.

6. The data processing method based on the FPGA implementation using the improved NAG algorithm for the dual-femtosecond laser ranging system according to claim 1, wherein:
in the step of hardware fitting the pulse envelope, an iteration termination condition is evaluated by an exit judgment module, wherein:
the evaluating of the iteration termination condition is based on a comparison result between a norm of a gradient vector and a preset threshold, the evaluation of the iteration termination condition also detects whether a current number of iterations reaches an upper limit, the iterations is terminated and the pulse peak time is output when the iteration termination condition is satisfied.

7. The data processing method based on the FPGA implementation using the improved NAG algorithm for the dual-femtosecond laser ranging system according to claim 1, wherein:
in the step of hardware fitting the pulse envelope, a learning rate is dynamically adjusted by a learning rate decay module, wherein:
in the step of the dynamically adjusting of the learning rate, an attenuation factor is calculated based on a number of iterations and a preset attenuation rate, the attenuation factor acts on an initial learning rate through an exponential function, and the adjusted learning rate is used to control a parameter update step size.

8. The data processing method based on the FPGA implementation using the improved NAG algorithm for the dual-femtosecond laser ranging system according to claim 1, wherein:
in the step of hardware fitting the pulse envelope, a momentum update module is used to fuse a gradient with a historical momentum, wherein:
the fusing of the gradient with the historical momentum is implemented by a weighted superposition of a current gradient and a momentum vector at a previous moment; a proportion of the weighted superposition is controlled by a learning rate and a momentum factor; a result of the fusing generates an updated momentum vector to accelerate parameter convergence.

9. The data processing method based on the FPGA implementation using the improved NAG algorithm for the dual-femtosecond laser ranging system according to claim 1, wherein:
in the step of hardware fitting the pulse envelope, a parameter updating module adjusts fitting parameters of a Gaussian function in combination with a momentum vector, wherein:
the adjusting of the fitting parameters is implemented by adding a parameter vector from a previous iteration to a updated momentum vector; the updated momentum vector is outputted by a momentum update module; and a result of the adjusting generates a new parameter vector to iteratively approach a desired solution of the pulse envelope.

10. The data processing method based on the FPGA implementation using the improved NAG algorithm for the dual-femtosecond laser ranging system according to claim 1, wherein:
in the step of calculating the distance value, the pulse peak time is substituted into the optical distance calculation formula, wherein:
the optical distance calculation formula is based on timing differences among a peak time of a reference pulse, a peak time of a target pulse, and the peak time of the reference pulse in a next cycle, the absolute distance is calculated by combining the timing differences with a speed of light, a refractive index of air, and a laser repetition frequency, the speed of light, the refractive index of air, and the laser repetition frequency are predefined constants.

11. A data processing system using an improved NAG algorithm for a dual-femtosecond laser ranging system, wherein the data processing system comprises:
a data acquisition module, configured to obtain discrete sampling points of a pulse signal, wherein the discrete sampling points include timestamps and measured values;
a parameter optimization module, connected to the data acquisition module and configured to output an desired learning rate and a learning rate decay rate through grid search based on the discrete sampling points;
a pulse envelope fitting module, connected to the parameter optimization module and deployed on an FPGA platform, wherein the pulse envelope fitting module includes;
a computing control module, configured to schedule an execution process through a finite state machine; and
a plurality of hardware sub-modules, configured to work collaboratively;
an on-chip BRAM dynamic cache module, connected to each module and configured to store intermediate variables; and
a distance calculation module, connected to the pulse envelope fitting module and configured to output an absolute distance based on an output pulse peak time.

12. The data processing system using the improved NAG algorithm for the dual-femtosecond laser ranging system according to claim 11, wherein the hardware sub-modules of the pulse envelope fitting module comprises:
a look-ahead position calculation module, configured to output a look-ahead position based on a parameter vector and a momentum vector;
an objective function calculation module, connected to the look-ahead position calculation module, and configured to output an objective function value based on the look-ahead position and the discrete sampling points;
a gradient calculation module, connected to the objective function calculation module, and configured to output a gradient vector based on the objective function value;
an exit judgment module, connected to the gradient calculation module, and configured to output an iteration termination signal based on the gradient vector;
a learning rate decay module, configured to output a dynamic learning rate based on the learning rate decay rate outputted by the parameter optimization module;
a momentum update module, connected to the gradient calculation module and the learning rate decay module, and configured to output an updated momentum vector based on the gradient vector and the dynamic learning rate; and
a parameter update module, connected to the momentum update module and the look-ahead position calculation module, and configured to output an updated parameter vector based on the updated momentum vector;
wherein the updated parameter vector outputted by the parameter update module contains a pulse peak time and is inputted into the distance calculation module.

13. The data processing system using the improved NAG algorithm for the dual-femtosecond laser ranging system according to claim 11, wherein the on-chip BRAM dynamic cache module implements a sequential overwrite storage strategy, wherein:
in response to a scheduling instruction from the computing control module, the on-chip BRAM dynamic cache module dynamically allocates a storage block to the currently activated hardware sub-module, immediately after an objective function calculation module completes a computation, releases the storage block allocated to the objective function calculation module, and allocates the released storage block to a gradient calculation module, and an upper limit of a cache space shared by all the hardware sub-modules is 5 BRAM units.

14. The data processing system using the improved NAG algorithm for the dual-femtosecond laser ranging system according to claim 11, wherein an input of the distance calculation module includes three types of pulse peak times outputted by the pulse envelope fitting module, wherein:
a first type of the three types of pulse peak times is a reference pulse peak time; a second type of the three types of pulse peak times is a target pulse peak time; a third type of the three types of pulse peak times is a next-cycle reference pulse peak time; and the distance calculation module outputs an absolute distance value by scalar multiplication and division, combined with constants of light speed, air refractive index, and laser repetition frequency.

15. The data processing system using the improved NAG algorithm for the dual-femtosecond laser ranging system according to claim 14, wherein:
when calculating the absolute distance value, the distance calculation module is configured to:
use the first type of pulse peak time as a time reference point; use the second type of pulse peak time to calculate a time delay of the second type of pulse peak time relative to the first type of pulse peak time; and use the third type of pulse peak time to calculate a time delay the third type of pulse peak time relative to the first type of pulse peak time to determine a complete period of a laser pulse.
